(19) United States
(12) Patent Application Publication
(10) Pub. No.: US 2004/0262752 A1
(43) Pub. Date: Dec. 30, 2004

(54) Semiconductor device

(76) Inventors: Fujio Ito, Hanno (JP); Hiromichi Suzuki, Tokyo (JP); Takafumi Konno, Hakodate (JP); Tsugio Umehara, Hakodate (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/860,488

(22) Filed: Jun. 4, 2004

(30) Foreign Application Priority Data
Jun. 5, 2003 (JP) 2003-160647

(51) Int. Cl. H01L 23/48

(52) U.S. Cl. 257/734

(57) ABSTRACT

A semiconductor chip has a plurality of electrodes arranged along one side thereof; a plurality of leads arranged outside the one side thereof in the same direction as the above side; a plurality of bonding wires electrically connecting the electrodes to the leads; and a resin sealing member sealing the semiconductor chip, the leads and the bonding wires. The leads include first leads, each having a terminal portion which is located on the side face of the resin sealing member and exposed from the rear surface thereof, and second leads, each having a terminal portion which is located on the inner side of the terminal portions of the first leads and exposed from the rear surface of the resin sealing member. The first leads and the second leads are arranged alternately. The plurality of bonding wires are connected to the respective leads on the inner side of the terminal portions of the first leads.

### CLAIM OF PRIORITY

The present application claims priority from Japanese application JP 2003-160647, filed on Jun. 5, 2003, the content of which is hereby incorporated by reference into this application.

### BACKGROUND OF THE INVENTION

The present invention relates to a semiconductor device. Specifically, it relates to a technology which is effective when applied to a semiconductor device having external terminals that are obtained by exposing part of each lead from the rear side (mounting side) of a resin sealing member.

For a semiconductor device which is manufactured by sealing a semiconductor chip having an integrated circuit with a resin, various package structures have been proposed and commercialized. One of them is known as a “QFN (Quad Flatpack Non-Leaded Package)”. Since this QFN type semiconductor device has a package structure in which leads electrically connected to the electrodes of a semiconductor chip are exposed from the rear surface of a resin sealing member and serve as external terminals, its planar size can be reduced as compared with a QFP (Quad Flatpack Package) semiconductor device having a package structure in which leads electrically connected to the electrodes of a semiconductor chip are projected from the side faces of a resin sealing member and are bent in a predetermined shape.

A lead frame is used in the manufacture of the QFN type semiconductor device. The lead frame is manufactured by punching a metal plate with a precision press and etching it to form a predetermined pattern. The lead frame has a plurality of product forming areas defined by a frame body, including an outer frame portion and inner frame portions, and a chip substrate for mounting a semiconductor chip (tub, die pad, chip mounting portion) and a plurality of leads having end portions (one end portions) situated around the chip substrate are arranged in each of the product forming areas. The chip substrate is supported by suspension leads which extend from the frame body of the lead frame. The other end portions opposite to the one end portions (distal ends) of the leads are supported on the frame body of the lead frame.

To manufacture a QFN type semiconductor device by using this lead frame, a semiconductor chip is fixed on the chip substrate of the lead frame; the electrodes of the semiconductor chip and the leads are electrically connected to each other by conductive wires; the semiconductor chip, wires, substrate, suspension leads, etc. are sealed with a resin to form a resin sealing member; and unnecessary portions of the lead frame are cut away.

The resin sealing member of the QFN type semiconductor device is formed by a transfer molding method which is suitable for mass production. The formation of the resin sealing member by the transfer molding method is carried out by positioning the lead frame between the upper mold and the lower mold of a metal mold, so that the semiconductor chip, leads, chip mounting portion, suspension leads, bonding wires, etc. are arranged in the cavity (resin filled portion) of the metal mold, and then a thermosetting resin is injected into the cavity of the metal mold.

An example of the QFN type semiconductor device is described in Japanese Unexamined Patent Publication No. 2001-189410 (patent document 1) and Japanese Patent No. 3072291 (patent document 2).

[patent document 1]

Japanese Unexamined Patent Publication No. 2001-189410

[patent document 2]

Japanese Patent No. 3072291

### SUMMARY OF THE INVENTION

The inventors of the present invention have studied the QFN type semiconductor device and have found the following problem.

The number of terminals (the number of pins) must be increased to improve the function and performance of an integrated circuit to be mounted on a semiconductor chip even in the QFN type semiconductor device. Since the formation of a large number of pins causes an increase in the planar size (package size) of a resin sealing member, the number of pins must be increased without changing the package size. To increase the number of pins without changing the package size, the leads must be reduced in size. However, the external terminals become small by reducing the size of the leads. As the external terminals must have a predetermined area to secure reliability at the time of mounting, they cannot be made too small. Therefore, when the number of pins is to be increased without changing the package size, since the number of terminals cannot be increased so much, the number of pins cannot be greatly increased.

To secure the area for the external terminals and increase the number of pins without changing the package size, it is effective that the terminal portions (used as external terminals) of the leads be selectively made wide and arranged in a zigzag manner in the arrangement direction of the leads. That is, first leads having a terminal portion situated near the side faces of the resin sealing member and second leads having a terminal portion situated on the inner side of the terminal portions of the first leads are arranged alternately in the same direction (each side of the resin sealing member) on each side of the semiconductor chip. However, when terminal portions are located at one end (chip side) of the leads and connected to wires as described in the above patent document 2, the bonding wires for connecting the electrodes of a semiconductor chip to the first leads become longer than bonding wires for connecting the electrodes of the semiconductor chip to the second leads. If the bonding wires become long, when the resin sealing member is formed by the transfer molding method, due to a “wire flow” in which the bonding wires are deformed by the flow of the resin injected into the cavity of the metal mold, a problem such as a short circuit between adjacent wires readily occurs, thereby reducing the production yield.

The bonding wires are connected to the electrodes of the semiconductor chip at one end and to the leads at the other end. Particularly, at the first and last stages of each group, the interval between adjacent bonding wires on the other end side becomes narrow and the bonding wires connected to the first leads extend over the terminal portions of the second leads, thereby causing a problem such as a short circuit between adjacent wires.

It is an object of the present invention to provide a technology capable of improving the production yield of semiconductor devices.

It is another object of the present invention to provide a technology capable of realizing a semiconductor device having a high production yield and which is suitable for increasing the number of pins.

The abovementioned and other objects and novel characteristics of the present invention will become apparent from the following description in this specification and the accompanying drawings.

Briefly described below are the effects obtained by representative examples of the invention disclosed in this application.

(1) According to one aspect of the present invention, there is provided a semiconductor device comprising: a semiconductor chip having a plurality of electrodes arranged on one side of its main surface along that side; a plurality of leads arranged outside the side of the semiconductor chip in the same direction as the side; a plurality of bonding wires for electrically connecting the plurality of electrodes of the semiconductor chip to the plurality of leads, respectively; and a resin sealing member for sealing the semiconductor chip, the plurality of leads and the plurality of bonding wires, wherein the plurality of leads include first leads each having a terminal portion which is located on the side face side of the resin sealing member and exposed from the rear surface of the resin sealing member, and second leads each having a terminal portion which is located on an inner side of the terminal portions of the first leads and exposed from the rear surface of the resin sealing member, the first leads and the second leads being arranged alternately, and the plurality of bonding wires are connected to the respective leads on the inner side of the terminal portions of the first leads.

(2) According to the above-described example (1), the plurality of leads extend straight toward the semiconductor chip from the side face of the resin sealing member.

(3) According to the above-described example (1), the first leads have a portion extending from their terminal portions toward the semiconductor chip.

(4) According to the above-described example (1), one ends of the first leads are situated on the semiconductor chip side of their terminal portions, and one ends of the second leads are situated at their terminal portions.

(5) According to the above-described example (1), the plurality of bonding wires include first bonding wires for electrically connecting the electrodes of the semiconductor chip to the respective first leads and second bonding wires for electrically connecting the electrodes of the semiconductor chip to the respective second leads, the first bonding wires are connected to the first leads on the semiconductor chip side of the terminal portions of the first leads, and the second bonding wires are connected to the terminal portions of the second leads.

(6) According to the above-described example (1), wire connection portions in which the first bonding wires are connected to the first leads and wire connection portions in which the second bonding wires are connected to the second leads are arranged almost linearly in the same direction as the arrangement direction of the plurality of leads.

(7) According to the above-described example (1), the plurality of bonding wires include first bonding wires for electrically connecting the electrodes of the semiconductor chip to the first leads and second bonding wires for electrically connecting the electrodes of the semiconductor chip to the second leads, and the first and second bonding wires are connected to the first and second leads on the inner side of the terminal portions of the second leads, respectively.

(8) According to another aspect of the present invention, there is provided a method of manufacturing a semiconductor device, comprising the steps of:

preparing a lead frame comprising leads, each having a first portion continuous to a second portion which is thicker than the first portion, and a heat stage having projections; and

connecting the electrodes of the semiconductor chip to the first portions of the leads by bonding wires while the first portions of the leads are mounted on the projections of the heat stage.

(9) According to another aspect of the present invention, there is provided a method of manufacturing a semiconductor device, comprising the steps of:

preparing a lead frame comprising leads, each having a first portion continuous to a second portion which is thicker than the first portion, and a chip substrate which is thinner than the second portions of the leads;

preparing a heat stage which has first projections at positions corresponding to the first portions of the leads and a second projection at a position corresponding to the chip substrate when the lead frame is positioned; and

connecting the electrodes of the semiconductor chip mounted on the chip substrate to the first portions of the leads by bonding wires while the first portions of the leads are positioned over the first projections and the chip substrate is positioned over the second projection.

### BRIEF DESCRIPTION OF THE DRAWINGS

FIG. 1 is a plan view showing the appearance of a semiconductor device according to Embodiment 1 of the present invention;

FIG. 2 is a bottom view showing the appearance of the semiconductor device according to Embodiment 1 of the present invention;

FIG. 3 is a enlarged view of a portion of FIG. 2;

FIG. 4 is a plan view showing the internal structure of the semiconductor device according to Embodiment 1 of the present invention;

FIG. 5 is an enlarged view of a portion of FIG. 4;

FIG. 6 is a bottom view showing the internal structure of the semiconductor device according to Embodiment 1 of the present invention;

FIGS. 7(a) and 7(b) are sectional views showing the internal structure of the semiconductor device according to Embodiment 1 of the present invention, in which FIG. 7(a) is a sectional view cut on line a-a of FIG. 3 and FIG. 7(b) is a sectional view cut on line b-b of FIG. 3;

FIG. 8 is an enlarged view of a portion of FIG. 7(a);

FIG. 9 is an enlarged view of a portion of FIG. 7(b);

FIG. 10 is a plan view showing a whole lead frame used in the manufacture of the semiconductor device according to Embodiment 1 of the present invention;

FIG. 11 is an enlarged view of a portion of FIG. 10;

FIGS. 12(a) and 12(b) are sectional views showing the chip mounting step in the production process of the semiconductor device according to Embodiment 1 of the present invention, in which FIG. 12(a) is a sectional view along the first leads and FIG. 12(b) is a sectional view along the second leads;

FIGS. 13(a) and 13(b) are sectional views showing that the lead frame positioned on a heat stage in the wire bonding step in the production process of the semiconductor device according to Embodiment 1 of the present invention, in which FIG. 13(a) is a sectional view along the first leads and FIG. 13(b) is a sectional view along the second leads;

FIG. 14 is a plan view showing the lead frame positioned on the heat stage in the wire bonding step in the production process of the semiconductor device according to Embodiment 1 of the present invention;

FIGS. 15(a) and 15(b) are sectional views showing the stage when wire bonding has been carried out in the wire bonding step in the production process of the semiconductor device according to Embodiment 1 of the present invention, in which FIG. 15(a) is a sectional view along the first leads and FIG. 15(b) is a sectional view along the second leads;

FIG. 16 is a plan view showing the stage when wire bonding has been carried out in the wire bonding step in the production process of the semiconductor wafer according to Embodiment 1 of the present invention;

FIGS. 17(a) and 17(b) are sectional views showing that the lead frame positioned in a metal mold in the molding step in the production process of the semiconductor device according to Embodiment 1 of the present invention, in which FIG. 17(a) is a sectional view along the first leads and FIG. 17(b) is a sectional view along the second leads;

FIG. 18 is a plan view showing that the lead frame positioned in the metal mold in the molding step in the production process of the semiconductor device according to Embodiment 1 of the present invention;

FIGS. 19(a) and 19(b) are sectional views showing that a resin is injected into the cavity of the metal mold in the molding step in the production process of the semiconductor device according to Embodiment 1 of the present invention, in which FIG. 19(a) is a sectional view along the first leads and FIG. 19(b) is a sectional view along the second leads;

FIG. 20 is a plan view of the lead frame sealed with the resin in the production process of the semiconductor device according to Embodiment 1 of the present invention;

FIG. 21 is a plan view of part of a lead frame according to a modification of Embodiment 1 of the present invention;

FIG. 22 is a plan view showing the internal structure of a semiconductor device according to Embodiment 2 of the present invention;

FIG. 23 is a sectional view cut on line a-a of FIG. 21;

FIG. 24 is a sectional view cut on line b-b of FIG. 21;

FIG. 25 is a plan view showing the internal structure of a semiconductor device according to Embodiment 3 of the present invention;

FIG. 26 is a sectional view cut on line a-a of FIG. 24;

FIG. 27 is a sectional view cut on line b-b of FIG. 24;

FIG. 28 is a plan view showing the internal structure of a semiconductor device according to Embodiment 4 of the present invention;

FIGS. 29(a) and 29(b) are sectional views showing the internal structure of the semiconductor device according to Embodiment 4 of the present invention, in which FIG. 29(a) is a sectional view cut on line a-a of FIG. 3 and FIG. 29(b) is a sectional view cut on line b-b of FIG. 3;

FIG. 30 is a plan view showing the internal structure of a semiconductor device according to Embodiment 5 of the present invention; and

FIG. 31 is a bottom view showing the internal structure of the semiconductor device according to Embodiment 5 of the present invention.

### DETAILED DESCRIPTION OF THE PREFERRED EMBODIMENTS

Preferred embodiments of the present invention will be described in detail with reference to the accompanying drawings. In the figures, elements having the same function are given the same reference symbols, and a repeated description thereof is omitted.

### EMBODIMENT 1

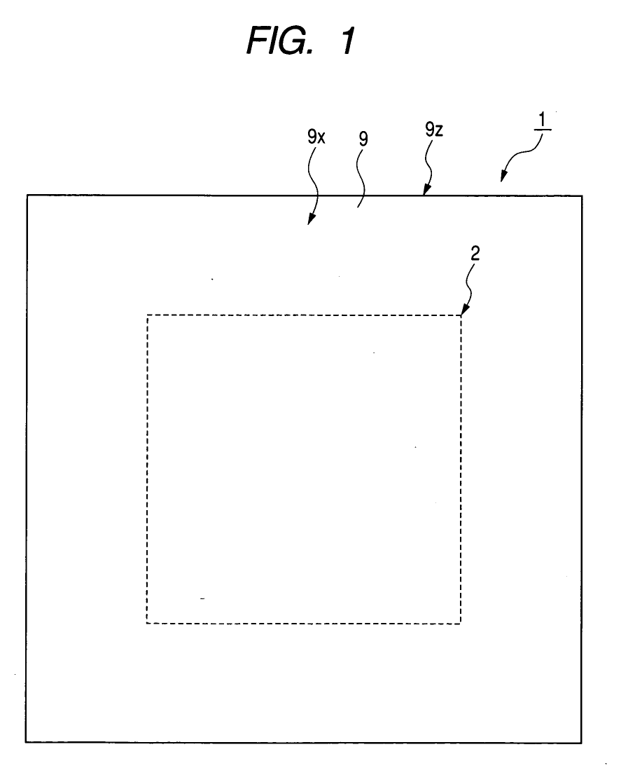

In Embodiment 1, the present invention is applied to a QFN type semiconductor device, and a description thereof will be presented with reference to FIGS. 1 through 7(b).

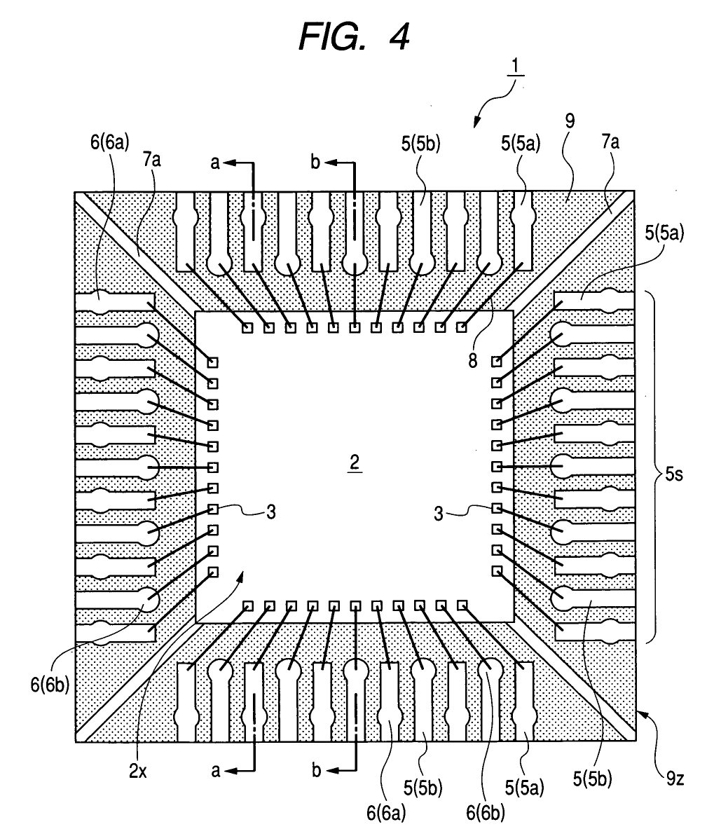

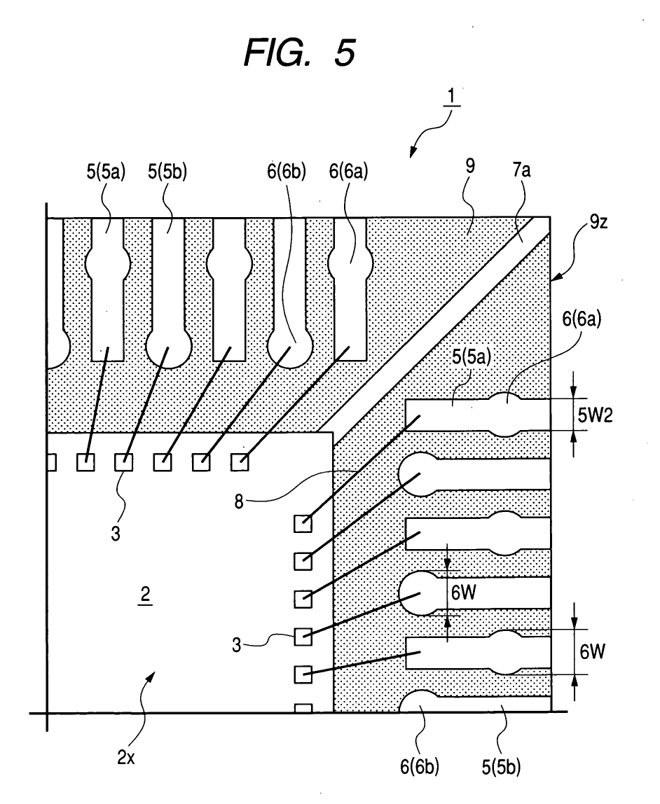

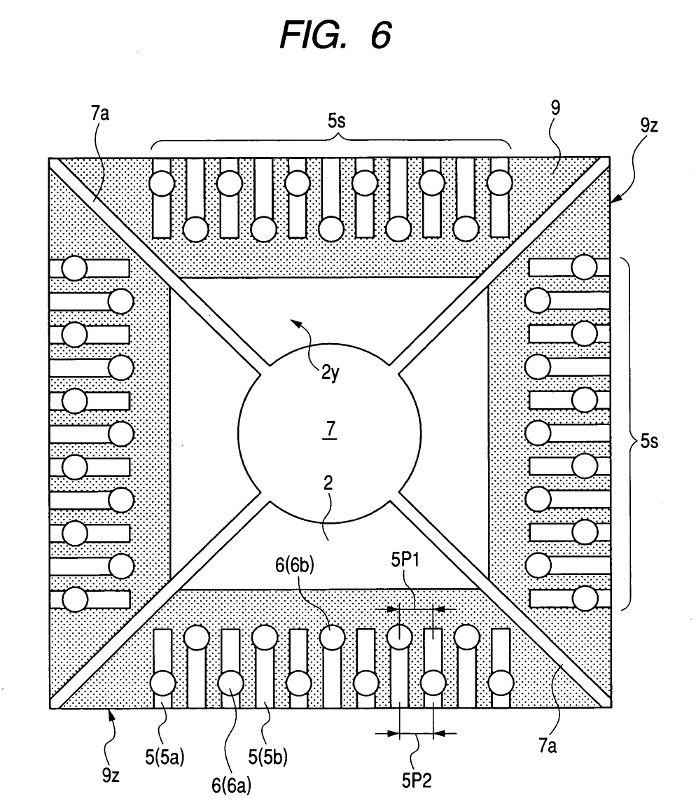

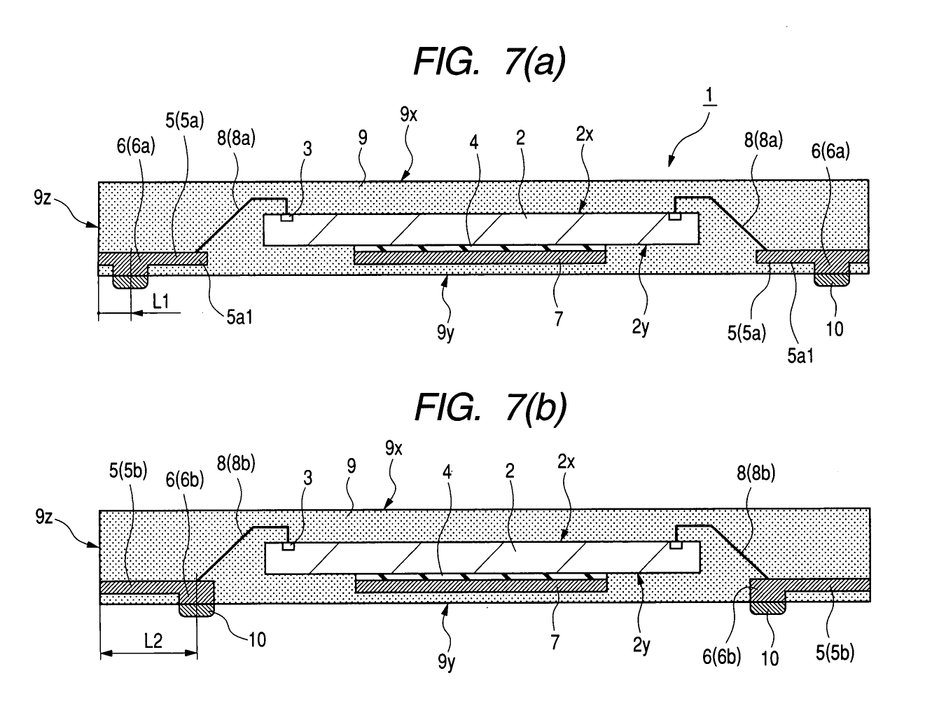

The semiconductor device 1 of Embodiment 1 has a package structure comprising a semiconductor chip 2, first to fourth groups 5s of leads 5, chip substrate (die pad, tub, chip mounting portion) 7, four suspension leads 7a, a plurality of bonding wires 8, a resin sealing member 9, etc., as shown in FIG. 4, FIG. 5, FIG. 6 and FIGS. 7(a) and 7(b). The semiconductor chip 2, the first to fourth groups 5s of leads 5, the chip substrate (die pad, tub) 7, the four suspension leads 7a and the plurality of bonding wires 8 are sealed with the resin sealing member 9. The semiconductor chip 2 is bonded and fixed to the main surface (top surface) of the chip substrate 7 by an adhesive 4, and the four suspension leads 7a are integrated with the chip substrate 7.

The planar shape perpendicular to the thickness direction of the semiconductor chip 2 is quadrangular, for example, square in this embodiment, as shown in FIG. 4 and FIG. 6. The semiconductor chip 2 is not limited to this. For example, the semiconductor chip 2 comprises a semiconductor substrate, a plurality of transistor elements formed on the main surface of this semiconductor substrate, a multi-layer wiring laminate including insulating layers and wiring layers formed over the main surface of the semiconductor substrate, and a surface protective layer (final protective layer) formed to cover this multi-layer wiring laminate. The insulating layers are each formed of a silicon oxide film. The wiring layers are each formed of a metal film, such as an aluminum (Al), aluminum alloy, copper (Cu) or copper alloy film. The surface protective layer is formed of a multi-layer laminate including an inorganic insulating film, such as a silicon oxide film or a silicon nitride film, and an organic insulating film.

The semiconductor chip 2 has a main surface (circuit formed surface) 2x and a rear surface 2y, which are opposite to each other, as shown in FIG. 4, FIG. 6 and FIGS. 7(a) and 7(b), and an integrated circuit is mounted on the main surface 2x of the semiconductor chip 2. The integrated circuit is mainly composed of transistor elements formed on the main surface of the semiconductor substrate and wirings formed in the multi-layer wiring laminate.

On the main surface 2x of the semiconductor chip 2, as shown in FIG. 4 and FIGS. 7(a) and 7(b), a plurality of bonding pads (electrodes) 3 are formed. The plurality of bonding pads 3 are arranged along each side of the semiconductor chip 2. The plurality of bonding pads 3 are formed in the uppermost wiring layer of the multi-layer wiring laminate of the semiconductor chip 2 and are exposed from bonding openings formed in the surface protective film of the semiconductor chip 2 corresponding to the bonding pads 3.

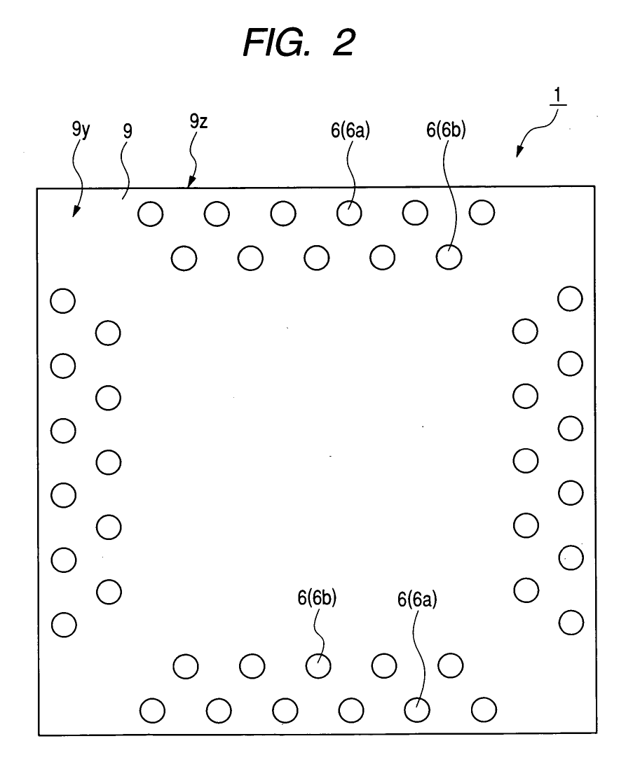

The planar shape perpendicular to the thickness direction of the resin sealing member 9 is quadrangular, for example, square in this embodiment, as shown in FIG. 1 and FIG. 2. The resin sealing member 9 has a main surface (top surface) 9x and a rear surface (under surface, mounting surface) 9y, which are opposite to each other, as shown in FIG. 1, FIG. 2 and FIGS. 7(a) and 7(b), and the planar size (outer size) of the resin sealing member 9 is larger than the planar size (outer size) of the semiconductor chip 2.

The resin sealing member 9 is formed from a biphenyl-based thermosetting resin containing a phenolic curing agent, silicone rubber and filler to reduce stress. To form the resin sealing member 9, a transfer molding method which is suitable for mass production is employed. In the transfer molding method, a metal mold which comprises a pot, runner, resin injection gate, cavity, etc. is used and a thermosetting resin is injected into the cavity from the pot through the runner and resin injection gate to form the resin sealing member.

For the manufacture of the resin sealed semiconductor device, an independent type transfer molding method may be employed in which a lead frame having a plurality of product forming areas is used and a semiconductor chip mounted in each product forming area is sealed with a resin independently, and a batch type transfer molding method may be employed in which a lead frame having a plurality of product forming areas is used and semiconductor chips mounted in the respective product forming areas are sealed with a resin in a batch manner. For the manufacture of the semiconductor device 1 of Embodiment 1, the batch type transfer molding method is employed.

The first to fourth groups 5s of leads are arranged along the four sides of the resin sealing member 9, as shown in FIG. 4, and the leads 5 of each group 5s are arranged in the same direction as each side (side of the resin sealing member 9) of the semiconductor chip 2. The leads 5 of each group 5s extend toward the semiconductor chip 2 from the side face 9z of the resin sealing member 9.

The plurality of bonding pads 3 of the semiconductor chip 2 are electrically connected to the respective leads 5 of the first to fourth groups 5s. In this Embodiment 1, electrical connections between the bonding pads 3 of the semiconductor chip 2 and the leads 5 are carried out by the bonding wires 8. One end of each of the bonding wires 8 is connected to each of the bonding pads 3 of the semiconductor chip 2, and the other end of each of the bonding wires 8 is connected to each of the leads 5 outside (around) the semiconductor chip 2. The bonding wires 8 are, for example, gold (Au) wires. To connect the wires 8, a nail head bonding (ball bonding) technique which makes use of ultrasonic vibration for thermocompression bonding is employed.

As shown in FIGS. 4 to 6 and FIGS. 7(a) and 7(b), the leads 5 of each group 5s include leads 5a and leads 5b. The leads 5a have a terminal portion 6a on the side face 9z side (near the side face 9z of the resin sealing member 9) of the resin sealing member, whereas the leads 5b have a terminal portion 6b on the inner side (semiconductor chip 2 side) of the terminal portions 6a of the leads 5a. That is, the terminal portions 6b of the leads 5b are arranged farther away from the side face 9z (peripheral edge) of the resin sealing member 9 than the terminal portions 6a of the leads 5a. As shown in FIGS. 7(a) and 7(b), the distance L2 of the terminal portions 6b from the side face 9z (peripheral edge) of the resin sealing member 9 is longer than the distance L1 of the terminal portions 6a from the side face 9z (peripheral edge) of the resin sealing member 9.

As shown in FIGS. 7(a) and 7(b), the terminal portions (6a, 6b) 6 are integrated with the leads (5a, 5b) 5, and portions other than the terminal portions 6 of the leads 5 are thinner than the terminal portions 6 (thickness of terminal portions 6>thickness of other portions). As shown in FIG. 5, the width 6W of the terminal portions (6a, 6b) 6 is larger than the width 5W2 of the end portions on the other end side (side close to the side face 9z of the resin sealing member 9) opposite to the one end side (side close to the semiconductor chip 2) of the leads 5.

As shown in FIG. 4 and FIG. 5, the leads 5 of each group 5s are arranged alternately such that the leads 5a and the leads 5b become adjacent to each other in one direction (along each side of the semiconductor chip 2 or each side of the resin sealing member 9).

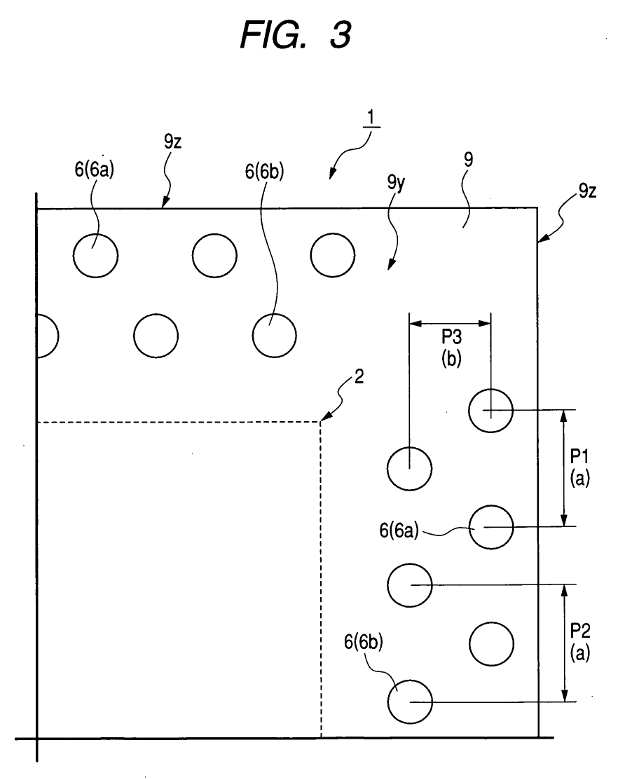

As shown in FIG. 2, FIG. 3 and FIGS. 7(a) and 7(b), the terminal portions (6a, 6b) 6 of the leads (5a, 5b) 5 are exposed from the rear surface 9y of the resin sealing member 9 and are used as external terminals. A solder layer 10 is formed on the end portions of the terminal portions 6 by plating or printing. The semiconductor device 1 of this Embodiment 1 is mounted by soldering the terminal portions (5a, 5b) to the electrodes (foot prints, lands, pads) of a wiring board.

The terminal portions 6 of the leads 5 of each group 5s are arranged in two rows in a zigzag manner along each side of the resin sealing member 9, as shown in FIGS. 2 to 6. The first row most close to each side of the resin sealing member 9 consists of the terminal portions 6a and the second row on the inner side of the first row consists of the terminal portions 6b. The pitch P1 of the terminal portions 6a of the first row and the pitch P2 (see FIG. 3) of the terminal portions 6b of the second row are wider than the pitch 5P2 (see FIG. 6) of the end portions on the other end side of the leads 5.

In this Embodiment 1, the pitch P2 of the terminal portions 6b and the pitch P1 of the terminal portions 6a are, for example, about 650 μm, and the pitch 5P2 of the end portions on the other end side of the leads 5 is, for example, about 400 μm.

The width 6W (see FIG. 5) of the terminal portions (6a, 6b) 6 is, for example, about 300 μm, and the width 5W2 (see FIG. 5) of the end portions on the other end side of the leads (5a, 5b) is, for example, about 200 μm.

The distance L1 (see FIG. 7) of the terminal portions 6a situated on the inner side (on the semiconductor chip 2 side) from the side face 9z (peripheral edge) of the resin sealing member 9 is, for example, about 250 μm, and the distance L2 (see FIG. 7) of the terminal portions 6b situated on the inner side (semiconductor chip 2 side) from the side face 9z (peripheral edge) of the resin sealing member 9 is, for example, about 560 μm.

The thickness of the terminal portions (6a, 6b) 6 is, for example, about 125 to 150 μm, and the thickness of portions other than the terminal portions 6 of the leads 5 is, for example, about 65 to 75 μm (see FIGS. 7(a) and 7(b)).

The semiconductor device 1 of this Embodiment 1 comprises the leads 5a having respective terminal portions 6a, which are exposed from the rear surface 9y of the resin sealing member 9 and are used as external terminals, and the leads 5b having respective terminal portions 6b, which are exposed from the rear surface 9y of the resin sealing member 9, are used as external terminals and are located on the inner side of the terminal portions 6a. The leads 5a and the leads 5b are arranged alternately in the same direction as each side (each side of the resin sealing member 9) of the semiconductor chip 2 in such a manner that they are adjacent to each other, and the width 6W of the terminal portions (6a, 6b) is larger than the width 5W2 of the end portions on the other end of the leads (5a, 5b) 5.

Due to this package structure, even when the leads (5a, 5b) 5 are reduced in width, areas for the terminal portions (6a, 6b) required for securing reliability at the time of mounting can be secured, thereby making it possible to increase the number of pins without changing the package size.

As shown in FIG. 4 to FIGS. 7(a) and 7(b), the plurality of leads (5a, 5b) 5 extend straight from the side faces 9z of the resin sealing member 9 toward the semiconductor chip 2, and one of the ends of the leads is situated outside the semiconductor chip 2, whereas the other of the ends of the leads is situated at the side faces 9z of the resin sealing member. In this Embodiment 1, each of the leads 5a has a portion (extension portion) 5a1 (see FIG. 7(a)) extending toward the semiconductor chip 2 from its terminal portion 6a and one end of the lead 5a is located on the inner side (the semiconductor chip 2 side) of its terminal portion 6a. One end of each of the leads 5b is located at its terminal portion 6b. The leads 5 are formed in a pattern such that the pitch 5P1 of the end portions on one end side and the pitch 5P2 of the end portions on the other end side of the leads 5 are almost the same.

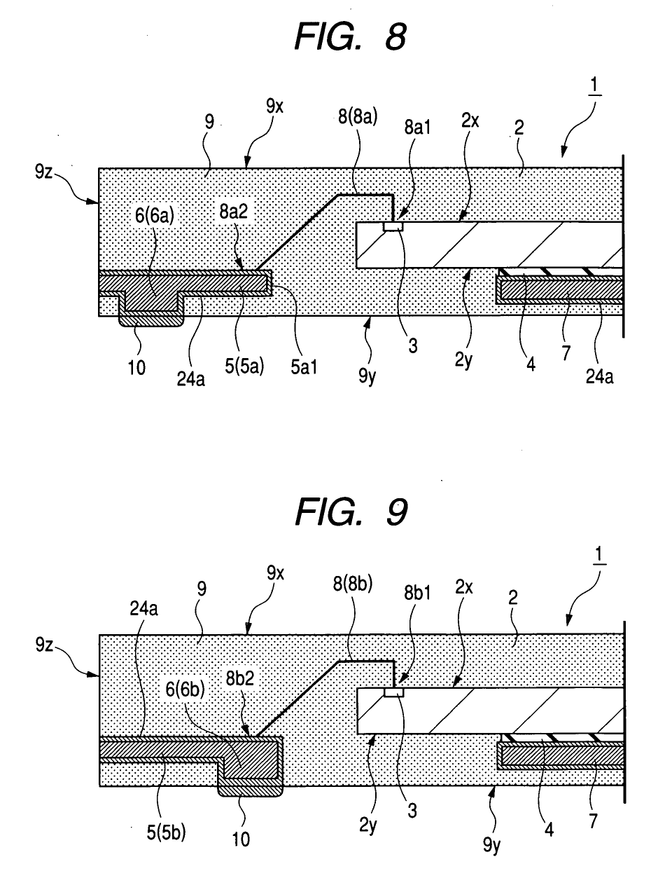

As shown in FIG. 4, FIG. 5 and FIGS. 7(a) and 7(b), the plurality of bonding wires 8 include a plurality of bonding wires 8a for electrically connecting the plurality of bonding pads 3 of the semiconductor chip 2 to the respective leads 5a and a plurality of bonding wires 8b for electrically connecting the plurality of bonding pads 3 of the semiconductor chip 2 to the respective leads 5b, and the plurality of bonding wires (8a, 8b) 8 are connected to the respective leads (5a, 5b) on the inner side (semiconductor chip 2 side) of the terminal portions 6a of the leads 5a. In this Embodiment 1, the bonding wires 8a have one end portions 8a1 which are connected to the respective bonding pads 3 of the semiconductor chip 2 and other end portions 8a2 which are connected to the respective extension portions (portions extending from the terminal portions 6a toward the semiconductor chip 2) 5a1 of the leads 5a, as shown in FIG. 8. As shown in FIG. 9, the bonding wires 8b have end portions 8b1 which are connected to the respective bonding pads 3 of the semiconductor chip 2 and other end portions 8b2 which are connected to the respective terminal portions 6b of the leads 5b.

In this Embodiment 1, connections between the other end portions 8a2 of the bonding wires 8a and the leads 5a and connections between the other end portions 8b2 of the bonding wires 8b and the leads 5b are carried out at a position where the distances from the semiconductor chip 2 become almost the same, in other words, at a position on a straight line extending in the same direction as the arrangement direction of the leads 5.

As shown in FIG. 6 and FIGS. 7(a) and 7(b), the planar size of the chip substrate 7 is smaller than the planar size of the semiconductor chip 2. That is, the semiconductor device 1 of this Embodiment 1 has a so-called “small tub structure” such that the planar size of the chip substrate 7 is made smaller than the planar size of the semiconductor chip 2. The small tub structure can rationalize productivity and reduce the cost because several different types of semiconductor chips which differ from one another in planar size can be mounted. The thickness of the chip substrate 7 is smaller than the thickness of the terminal portions 6 of the leads 5 and almost the same as the thickness of portions other than the terminal portions 6 of the leads 5.

As for the arrangement of the terminal portions 6 in this Embodiment 1, as shown in FIG. 3, when the pitch P1 of the terminal portions 6a of the first row and the pitch P2 of the terminal portions 6b of the second row are represented by “a” and the pitch (pitch between two rows) between the terminal portions 6a of the first row and the terminal portions 6b of the second row is represented by “b”, the relationship represented by expression (1) is established.

B∠√3/2×a (1)

A plating layer 24a essentially composed of palladium (Pd) is formed on the wire connection portions of the leads 5 of each group 5s in order to enhance the bondability between the leads 5 and the bonding wires 8, as shown in FIG. 8 and FIG. 9. The plating layer 24a essentially composed of Pd has higher adhesion to the resin of the resin sealing member 9 than a plating layer essentially composed of silver (Ag). In this Embodiment 1, the plating layer 24a is formed to cover the leads 5 and the chip substrate 7.

By plating with Pd, Au wire bonding is made possible at any portion of the leads 5.

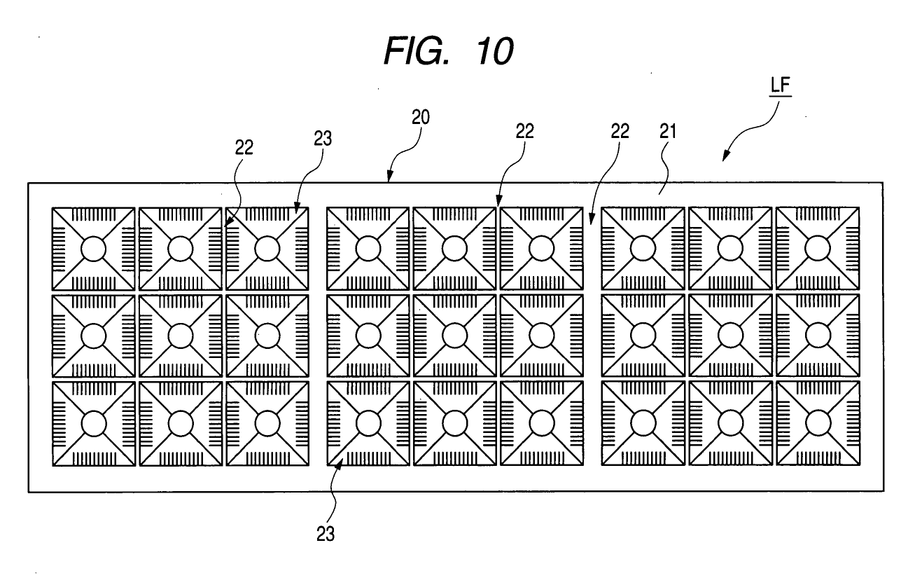

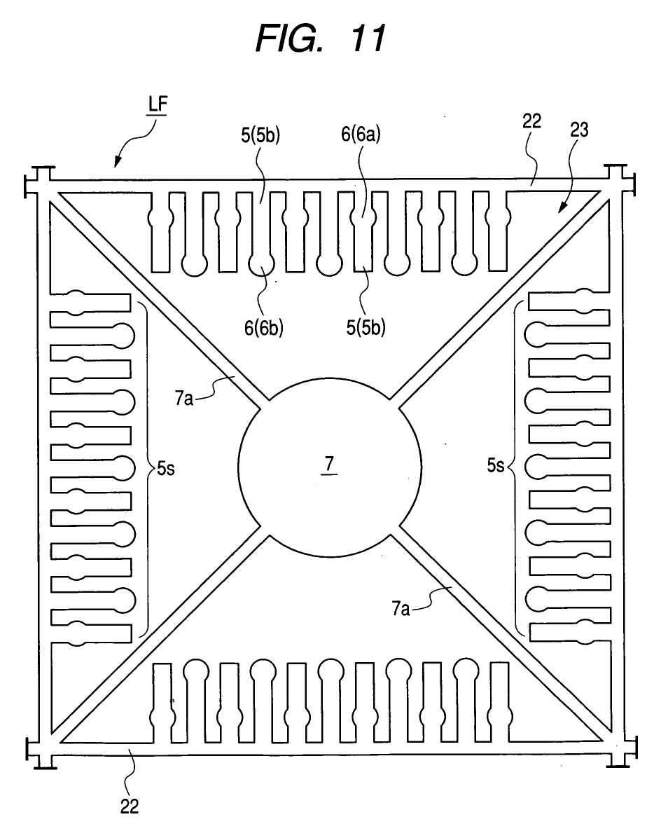

The lead frame used for the manufacture of the semiconductor device 1 will be described with reference to FIG. 10 and FIG. 11.

FIG. 10 is a plan view showing the entire lead frame used for the manufacture of the semiconductor device according to Embodiment 1.

FIG. 11 is a partially enlarged plan view of FIG. 10.

As shown in FIG. 10, the lead frame LF has a multiple structure in which a plurality of product forming areas (device forming areas) 23 defined by a frame body (substrate) 20 including an outer frame portion 21 and inner frame portions 22 are arranged in a matrix. In each of the product forming areas 23, as shown in FIG. 11, first to fourth groups 5s of leads 5 are arranged. The planar shape of the product forming area 23 is quadrangular, and the first to fourth groups 5s of leads are arranged corresponding to the four portions of the frame body 20 surrounding the product forming area 23. The leads 5 of each group 5s include a plurality of leads 5a and a plurality of leads 5b which are arranged alternately in one direction so that they are adjacent to each other. The groups 5s of leads 5 are connected to the respective portions (outer frame portion 21, inner frame portion 22) of the frame body 20. The plating layer essentially composed of palladium (Pd) is formed on the wire connection portions of the leads 5 of each group 5s to improve bondability between the leads 5 and the bonding wires.

To manufacture the lead frame LF, a metal plate made from copper (Cu), Cu alloy or iron (Fe)-nickel (Ni) alloy and having a thickness of 125 μm to 150 μm is prepared, and portions for forming the leads 5 of the metal plate are covered with a photoresist film on one side. Portions for forming the terminal portions 6 are covered with a photoresist film on both sides. In this state, the metal plate is etched with a chemical liquid to reduce the thickness of the metal plate in areas covered with the photoresist film on one side to 65 μm to 75 μm (half etching). By etching with this method, the metal plate in areas not covered with the photoresist film on both sides completely disappears and leads 5 having a thickness of 65 μm to 75 μm are formed in areas covered with the photoresist film on one side. Since the metal plate in areas covered with the photoresist film on both sides is not etched with the chemical liquid, projecting terminal portions 6 having the same thickness (125 μm to 150 μm) as that before etching are formed. Thereafter, the photoresist films are removed and a plating layer is formed on the leads 5 to complete the lead frame LF shown in FIG. 8 and FIG. 9.

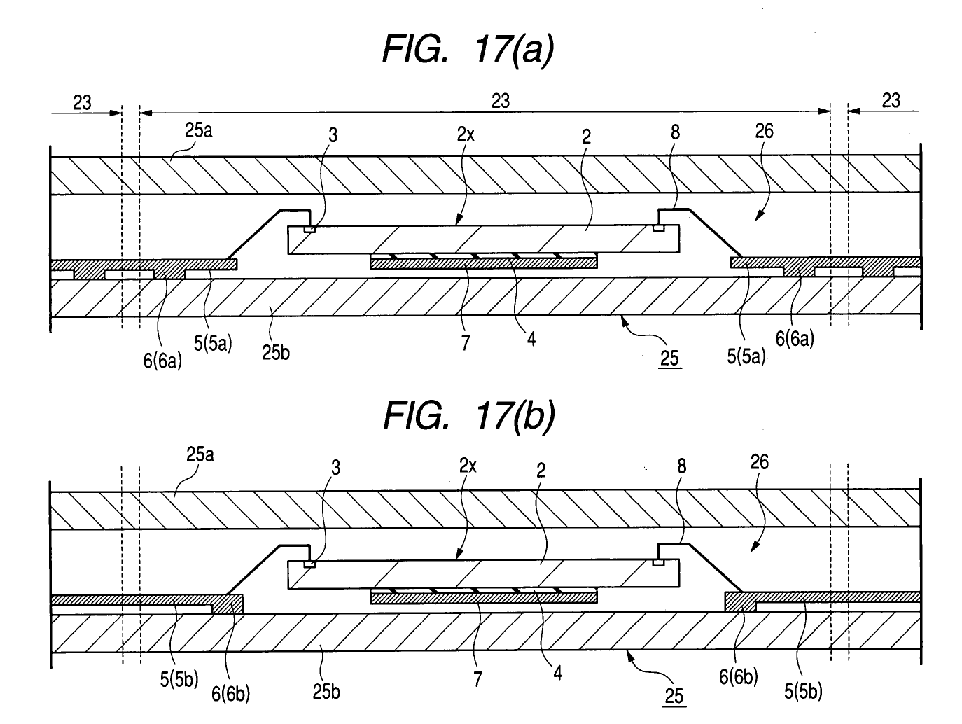

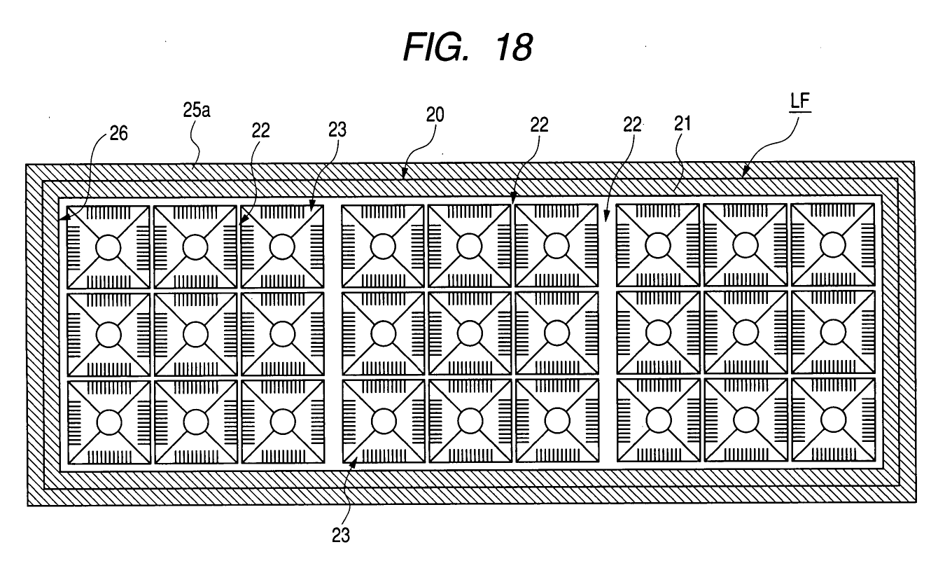

A description will be given of a metal mold used for the manufacture of the semiconductor device 1, with reference to FIGS. 17(a) and 17(b) and FIG. 18.

FIGS. 17(a) and 17(b) are sectional views showing that the lead frame is positioned in the metal mold in the molding step in the production process of the semiconductor device, in which FIG. 17(a) is a sectional view as seen along the first leads and FIG. 17(b) is a sectional view as seen along the second leads.

FIG. 18 is a plan view showing that the lead frame is positioned in the metal mold in the molding step in the production process of the semiconductor device.

As shown in FIGS. 17(a) and 17(b) and FIG. 18, the metal mold 25 has an upper mold 25a and a lower mold 25b, and further a pot, cull portion, runner, resin injection gate, cavity 26, air vent, etc., though the invention is not limited to this. The lead frame LF is positioned between the mating surfaces of the upper mold 25a and the lower mold 25b of the metal mold 25. The cavity 26 into which the resin is injected is formed by the upper mold 25a and the lower mold 25b when the mating surface of the upper mold 25a is opposed to the mating surface of the lower mold 25b. In this Embodiment 1, the cavity 26 of the metal mold 25 is formed by a depression formed in the upper mold 25a and the lower mold 25b, though the invention is not limited to this. The cavity 26 has a planar size large enough to store a plurality of product forming areas of the lead frame LF.

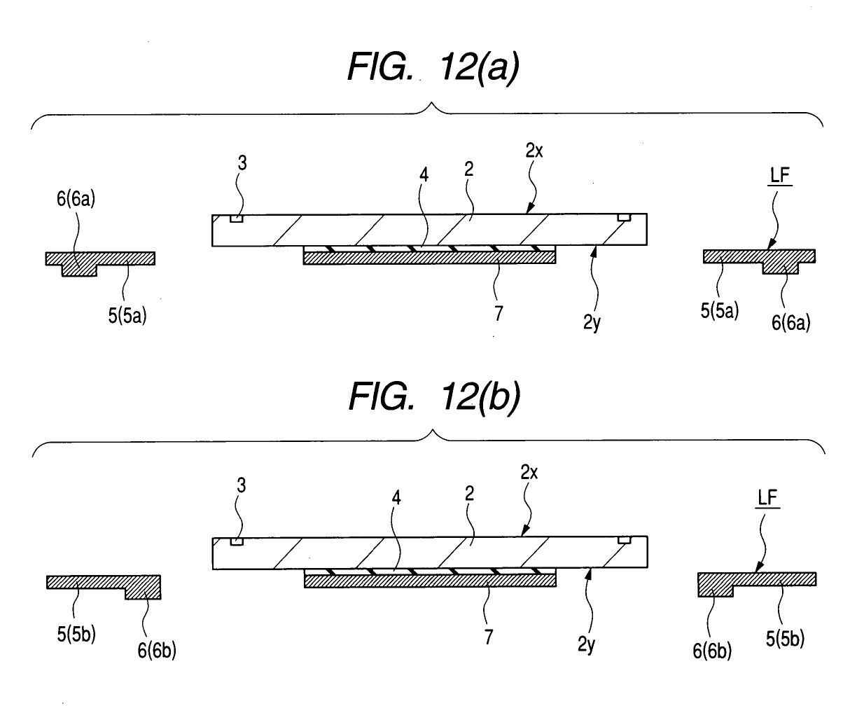

The manufacture of the semiconductor device 1 will be described with reference to FIGS. 12(a) and 12(b) to 20.

FIGS. 12(a) and 12(b) are sectional views showing the chip mounting step in the production process of the semiconductor device, in which FIG. 12(a) is a sectional view as seen along the first leads and FIG. 12(b) is a sectional view as seen along the second leads.

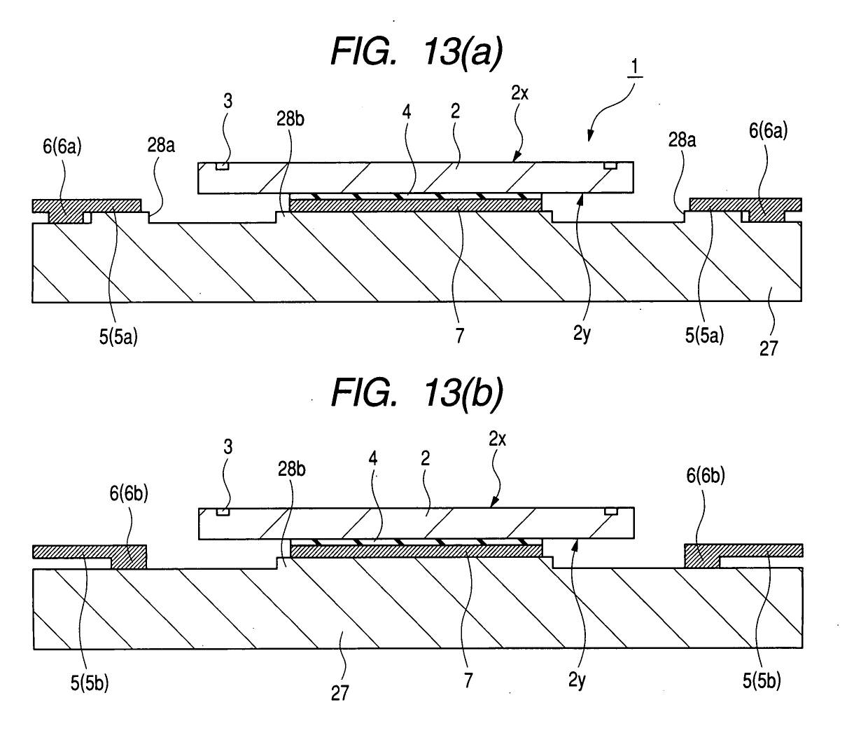

FIGS. 13(a) and 13(b) are sectional views showing that the lead frame is positioned on a heat stage in the wire bonding step in the production process of the semiconductor device, in which FIG. 13(a) is a sectional view as seen along the first leads and FIG. 13(b) is a sectional view as seen along the second leads.

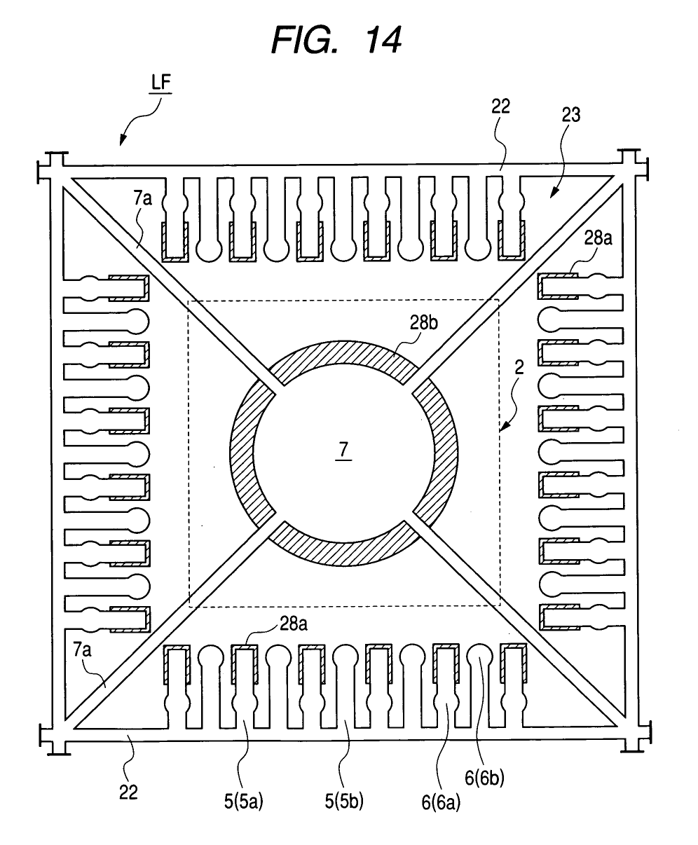

FIG. 14 is a plan view showing that the lead frame is positioned on the heat stage in the wire bonding step in the production process of the semiconductor device.

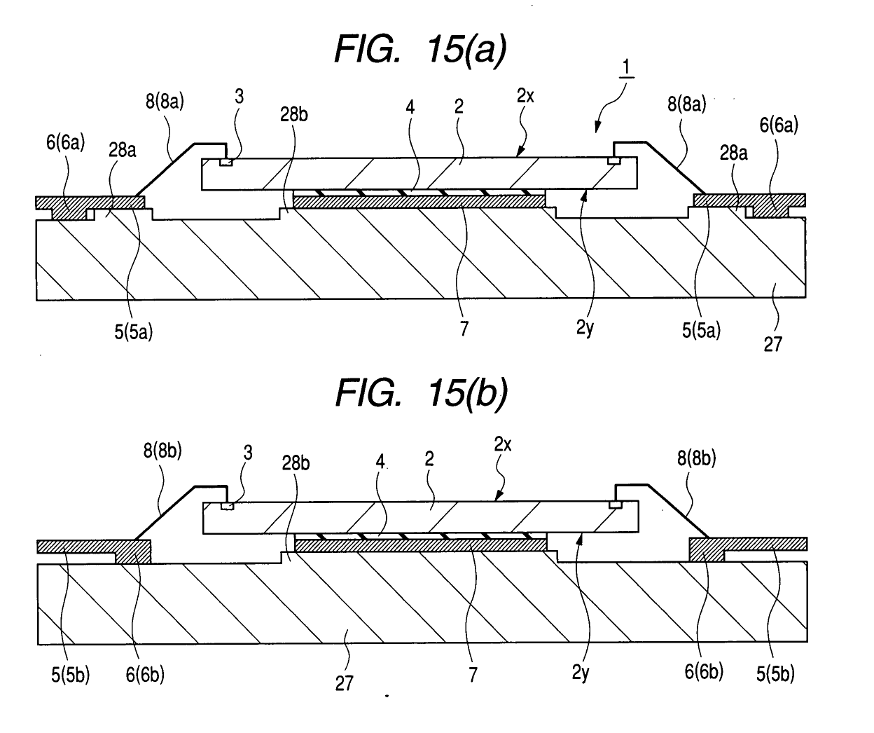

FIGS. 15(a) and 15(b) are sectional views showing that wire bonding has been carried out in the wire bonding step in the production process of the semiconductor device, in which FIG. 15(a) is a sectional view as seen along the first leads and FIG. 15(b) is a sectional view as seen along the second leads.

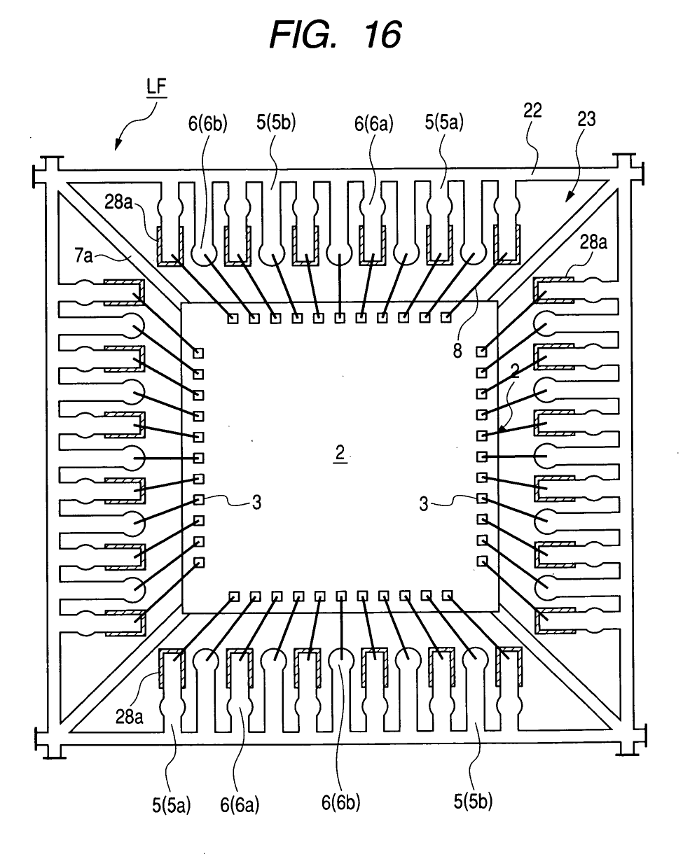

FIG. 16 is a plan view showing that wire bonding has been carried out in the wire bonding step in the production process of the semiconductor device.

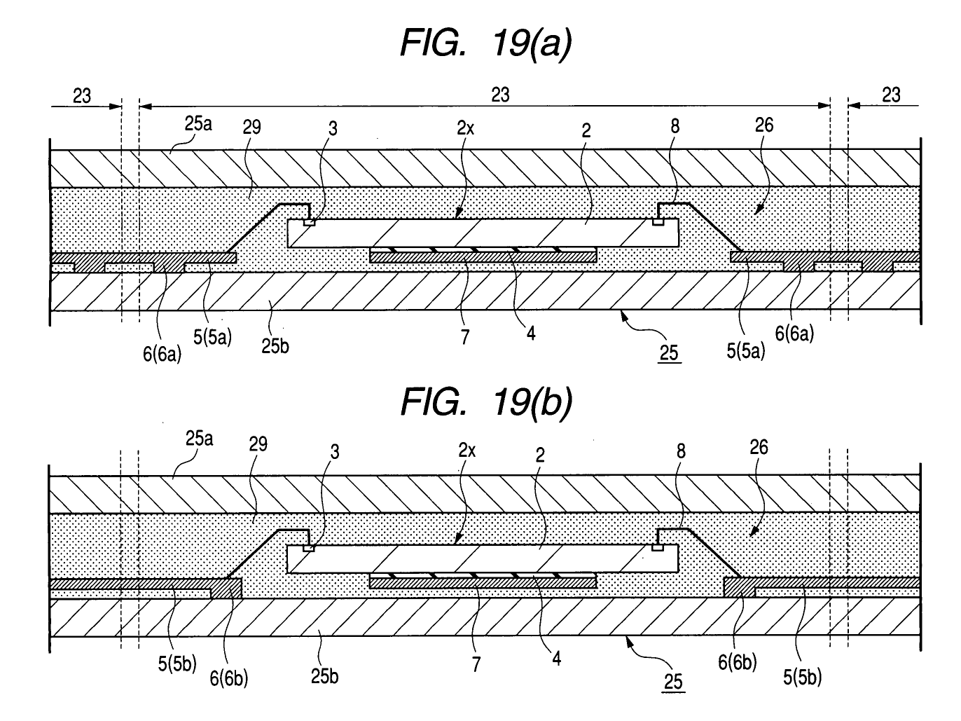

FIGS. 19(a) and 19(b) are sectional views showing that the resin is injected into the cavity of the metal mold in the molding step in the production process of the semiconductor device, in which FIG. 19(a) is a sectional view as seen along the first leads and FIG. 19(b) is a sectional view as seen along the second leads.

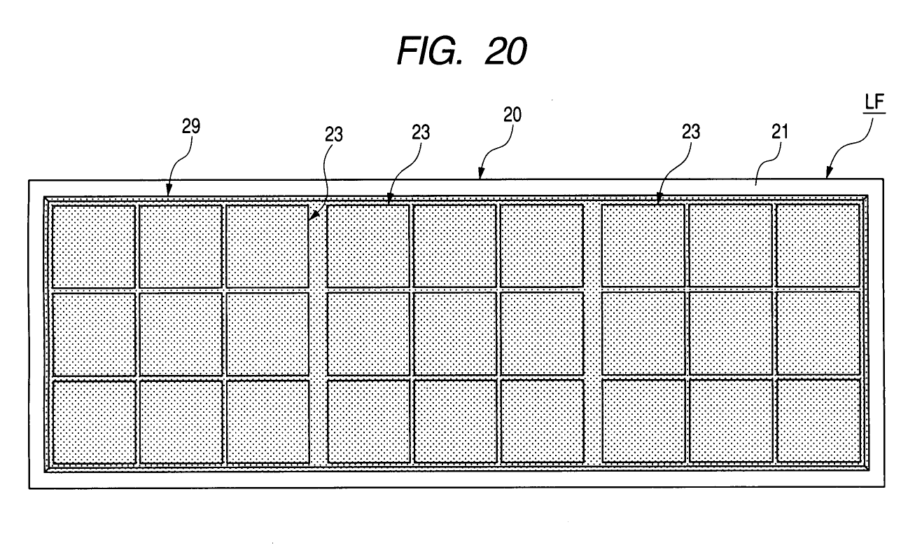

FIG. 20 is a plan view of the lead frame sealed with a resin in the production process of the semiconductor device.

The lead frame LF shown in FIG. 10 and FIG. 11 is prepared and then the semiconductor chip 2 is bonded and fixed to the lead frame LF, as shown in FIGS. 12(a) and 12(b). Bonding and fixing between the lead frame LF and the semiconductor chip 2 is carried out with an adhesive 4 in such a manner that the rear surface 2y of the semiconductor chip 2 is bonded and fixed to the main surface of the chip substrate 7.

As shown in FIGS. 13(a) and 13(b) and FIG. 14, the lead frame LF is positioned and mounted on the heat stage 27. When the lead frame LF is positioned on the heat stage 27, the heat stage 27 has projections 28a at positions corresponding to the extension portions 5a1 of the leads 5a and a projection 28b at a position corresponding to the chip substrate 7. That is, the lead frame LF is positioned on the heat stage 27 in such a manner that the extension portions 5a1 of the leads 5a of the lead frame LF come into contact with the projections 28a of the heat stage 27, the chip substrate 7 comes into contact with the projection 28b of the heat stage 27, and the terminal portions 6a of the leads 5a and the terminal portions 6b of the leads 5b come into contact with surfaces lower than the projections (28a, 28b) of the heat stage 27.

While the lead frame LF is positioned on the heat stage 27, as described above, as shown in FIGS. 15(a) and 15(b) and FIG. 16, the plurality of bonding pads 3 arranged on the main surface 2x of the semiconductor chip 2 and the plurality of leads 5 are electrically connected to each other by the plurality of bonding wires 8, respectively.

In this step, the bonding wires 8a are connected to the respective bonding pads 3 of the semiconductor chip 2 at one end and to the respective extension portions 5a1 of the leads 5a at the other end. The bonding wires 8b are connected to the respective bonding pads 3 of the semiconductor chip 2 at one end and to the respective terminal portions 6b of the leads 5b at the other end.

As shown in FIGS. 17(a) and 17(b) and FIG. 18, the lead frame LF is positioned between the upper mold 25a and the lower mold 25b of the metal mold 25.

The positioning of the lead frame LF is carried out while the plurality of product forming areas 23 are positioned in the cavity 26, that is, the semiconductor chip 2, leads 5 and bonding wires 8 of each product forming area 23 are positioned in the cavity 26.

The positioning of the lead frame LF is carried out while the terminal portions 6 of the leads 5 are in contact with the inner wall of the cavity 26 opposed to the terminal portions 6.

While the lead frame LF is positioned, a thermosetting resin, for example, is injected into the cavity 26 from the pot of the metal mold 25 through the cull portion, runner and resin injection gate to form the resin sealing member 29, as shown in FIG. 20. The semiconductor chip 2, the plurality of leads 5, the plurality of bonding wires 8, etc. of each product forming area 23 are sealed with the resin sealing member 29, as shown in FIG. 20.

Then, the lead frame LF is taken out from the metal mold 25, a solder layer 10 is formed on the surfaces of the terminal portions 6 exposed from the rear surface of the resin sealing member 29 in each product forming area 23 by plating or printing, and the lead frame LF and the resin sealing member 29 are divided into pieces corresponding to the product forming areas 23 by dicing to obtain individual resin sealing members 9, thereby almost completing the semiconductor devices 1 of this Embodiment 1 shown in FIGS. 1 to 9.

In the wire bonding step in the production process of the semiconductor device 1, the leads 5a have an extension portion 5a1 extending from the terminal portion 6a toward the semiconductor chip 2, and the bonding wires 8a are connected to the respective bonding pads 3 of the semiconductor chip 2 at one end and to the respective extension portions 5a1 of the leads 5a at the other end. The length of each of the bonding wires 8a for electrically connecting the bonding pads 3 of the semiconductor chip 2 to the leads 5 can be reduced according to the above constitution, as compared with a case where the wires are connected to the terminal portions 6a of the leads 5a. Therefore, when the resin sealing member is formed by the transfer molding method, such inconvenience as a short circuit between adjacent wires caused by so-called “wire flow” in which the bonding wires 8 are deformed by the flow of the resin injected into the cavity 26 of the metal mold 25 can be suppressed. As a result, the production yield of the semiconductor device 1 can be improved.

Since a phenomenon in which the interval between adjacent bonding wires on the other end side becomes narrow at the first and last stages of each group and a phenomenon in which the bonding wires 8a connected to the leads 5a extend over the terminal portions 6b of the leads 5b can be suppressed, such inconvenience as a short circuit between adjacent wires can also be suppressed.

Since a short circuit between adjacent wires can be suppressed, the semiconductor device 1, which has a high production yield and is suitable in increasing the number of pins, can be manufactured.

In the wire bonding step in the production process of the semiconductor device 1, as shown in FIG. 13 and FIG. 14, the lead frame LF is positioned on the heat stage 27 in such a manner that the extension portions 5a1 of the leads 5a come in contact with the projections 28a of the heat stage 27, the chip substrate 7 comes in contact with the projection 28b of the heat stage 27, and the terminal portions 6a of the leads 5a and the terminal portions 6b of the leads 5b come in contact with the surfaces lower than the projections (28a, 28b) of the heat stage 27. In this state, wire bonding is carried out. When wire bonding is carried out in this state, the lead frame LF can be supported on the heat stage 27 stably, thereby making it possible to prevent such inconvenience as the deformation of the leads 5 and the dislocation of the semiconductor chip 2.

Since heat is transmitted to the semiconductor chip 2 from the heat stage 27 efficiently and also to the extension portions 5a1 of the leads 5 and the terminal portions 6b of the leads 5b efficiently as well, a wire connection failure by the bonding wires 8a and 8b can be prevented.

In this Embodiment 1, the other ends of the wires are connected to the terminal portions 6b of the leads 5b. Like the leads 5a, the leads 5b may have extension portions which extend toward the semiconductor chip 2 from the terminal portions 6b, and the other ends of the wires may be connected to the extension portions of the leads 5b. In this case, the length of each of the wires connected to the leads 5b becomes short.

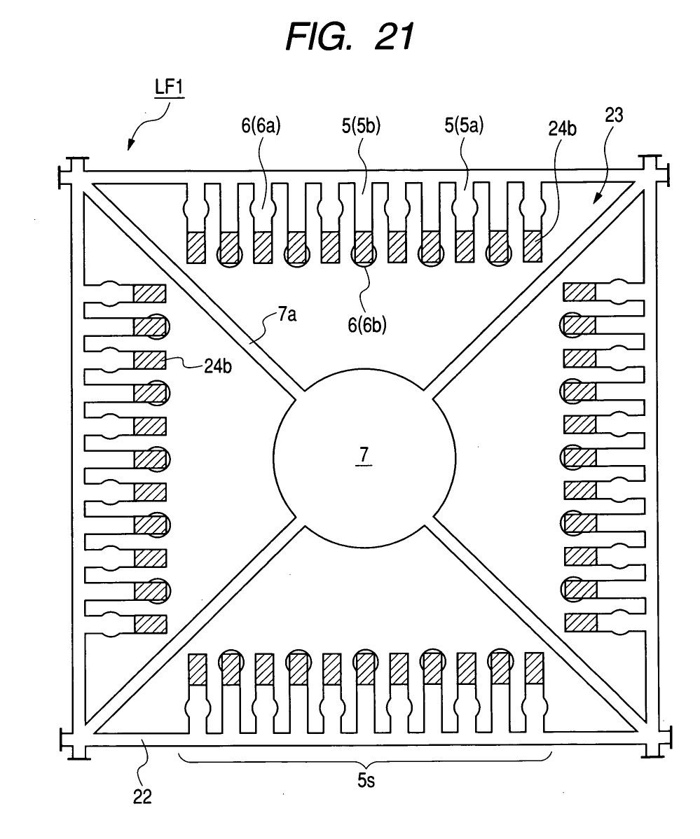

FIG. 21 is a plan view of part of a lead frame which represents a modification of this Embodiment 1.

In the above-described Embodiment 1, the plating layer 24a essentially composed of Pd is formed on the leads 5 to improve the bondability between the leads 5 and the bonding wires. As shown in FIG. 21, a plating layer 24b essentially composed of Ag may be formed on the straight portions of the leads 5, as shown in FIG. 21. In this case, Au wire bonding is made possible by plating the straight portions of the leads 5 with Ag.

### EMBODIMENT 2

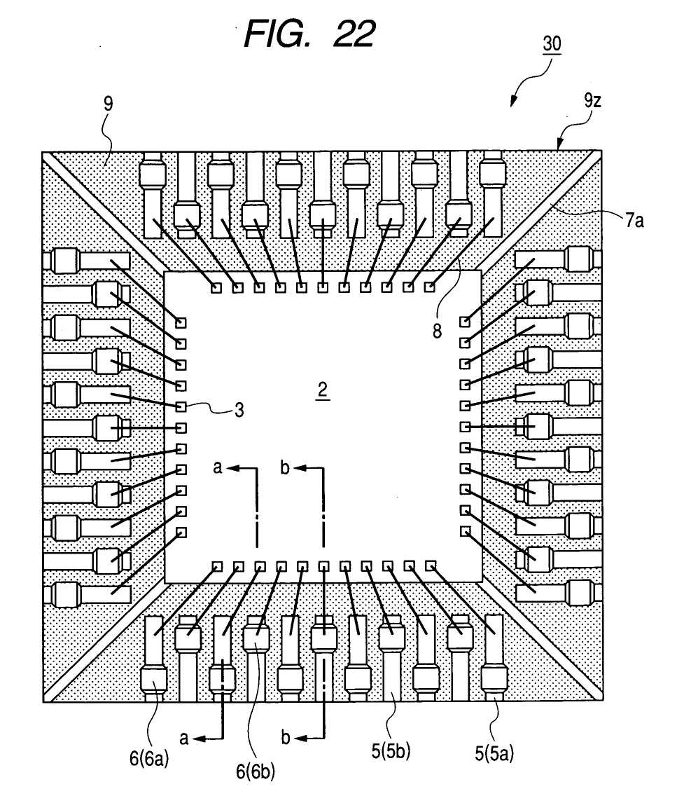

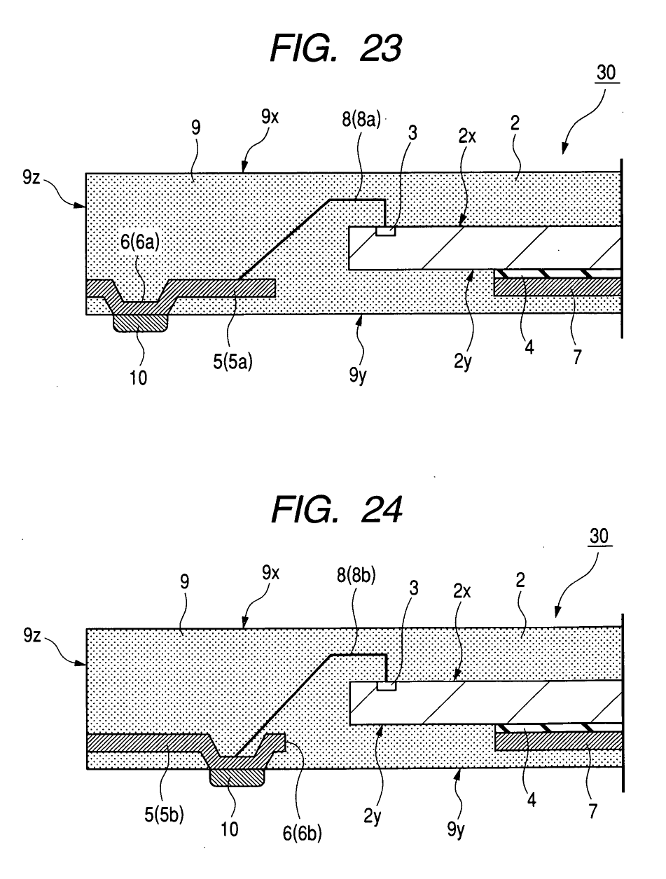

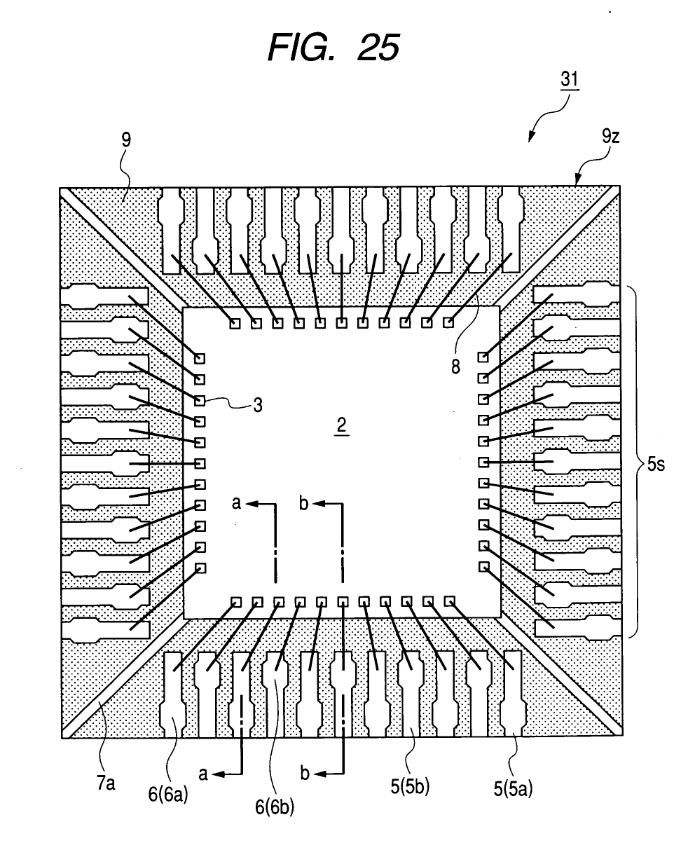

FIG. 22 is a plan view showing the internal structure of a semiconductor device according to Embodiment 2 of the present invention, FIG. 23 is a sectional view cut on line a-a of FIG. 21, and FIG. 24 is a sectional view cut on line b-b of FIG. 21.

As shown in FIGS. 22 to 24, the semiconductor device 30 of this Embodiment 2 is basically identical to the above-described Embodiment 1, except for the following point.

The semiconductor device 30 of this Embodiment 2 has a package structure in which the terminal portion 6 of each of the leads 5 is formed by bending part of the lead 5. This package structure is obtained by using a lead frame manufactured by pressing or etching a metal plate to form a predetermined lead pattern and then bending part of each of the leads 5 to form the terminal portions 6.

Since one end portion of each of the leads will greatly shift relative to one another when thick terminal portions are formed by bending winding leads, the formation of the terminal portions 6 by bending is difficult. When thick terminal portions are formed by bending straight leads, positional differences among the one end portions of the leads will be small as compared with winding leads. Therefore, the terminal portions 6 can be formed by bending. Consequently, a semiconductor device having a high production yield and which is suitable for increasing the number of pins can be manufactured at a low cost in accordance with this Embodiment 2.

### EMBODIMENT 3

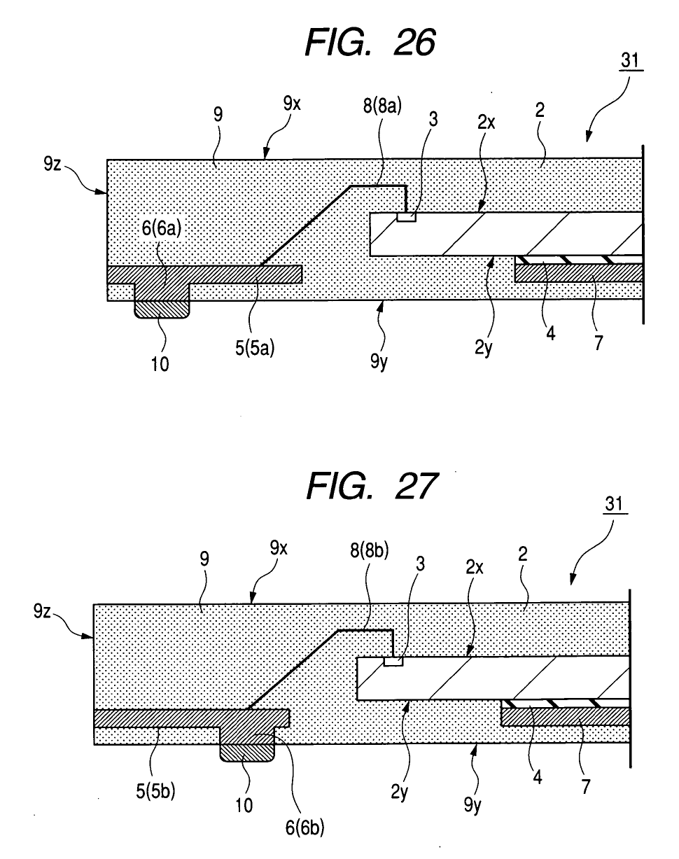

FIG. 25 is a plan view showing the internal structure of a semiconductor device according to Embodiment 3 of the present invention, FIG. 26 is a sectional view cut on line a-a of FIG. 24, and FIG. 27 is a sectional view cut on line b-b of FIG. 24.

As shown in FIGS. 25 to 27, the semiconductor device 31 of this Embodiment 3 is basically identical to the above-described Embodiment 1, for except the following point.

That is, the leads 5 of this Embodiment 3 are formed by coining thicker terminal portions 6 than other portions. The terminal portions 6 of this Embodiment 3 are formed by punching a metal plate with a precision press to form straight leads and coining the leads in the manufacture of the lead frame.

Since the one end portions of the leads will greatly shift relative to one another when thick terminal portions are formed by coining winding leads, the formation of the terminal portions 6 by coining is difficult. However, when thick terminal portions are formed by coining straight leads, positional differences among the one end portions of the leads will be small as compared with winding leads. Therefore, the terminal portions 6 can be formed by coining. Consequently, a semiconductor device which has a high production yield and which is suitable for increasing the number of pins can be manufactured at a low cost in accordance with this Embodiment 3 as well.

### EMBODIMENT 4

In this Embodiment 4, the present invention is applied to a laminate type semiconductor device.

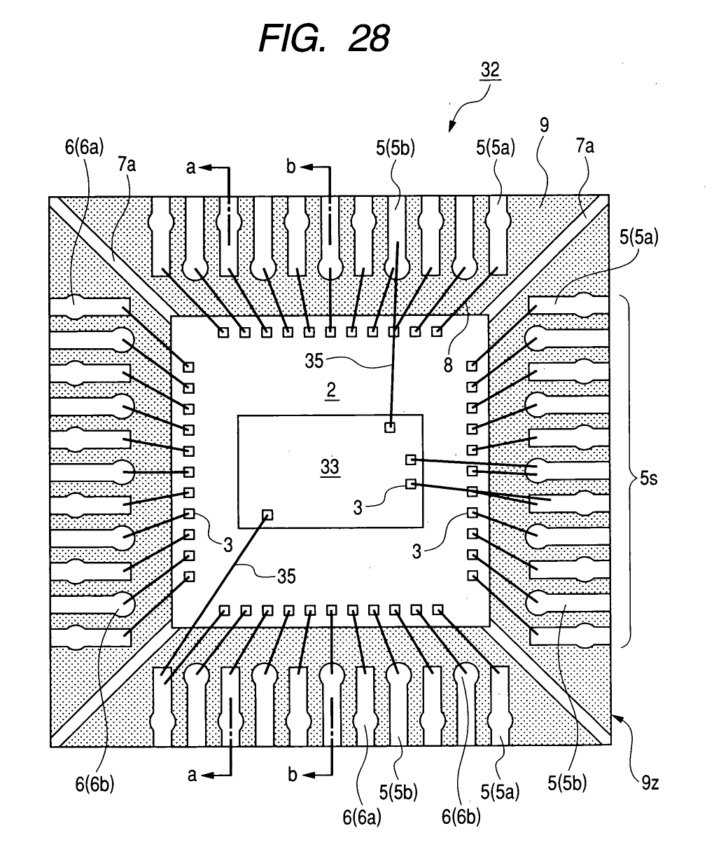

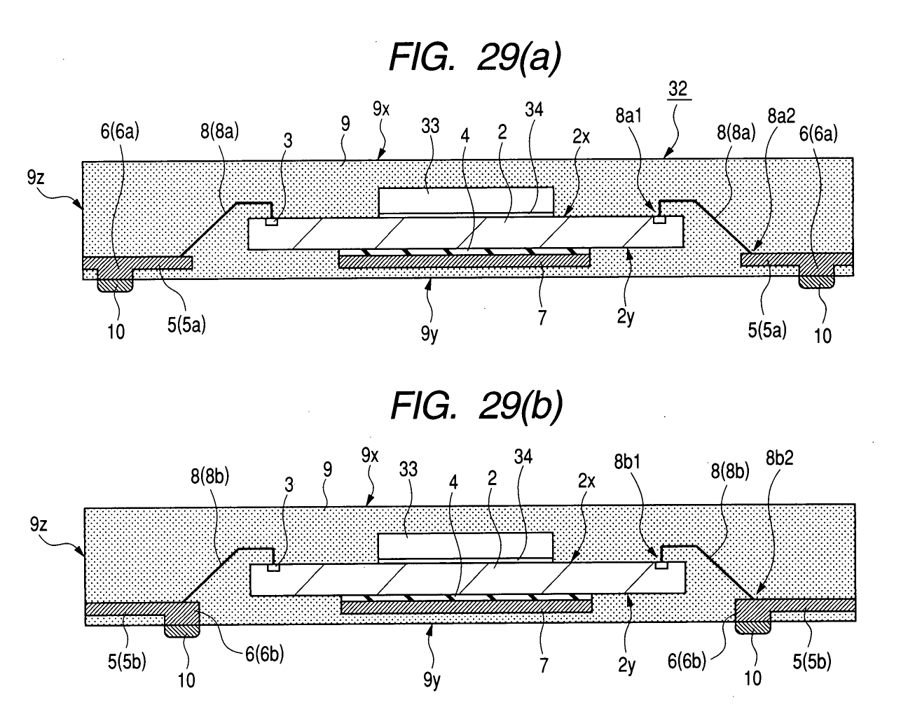

FIG. 28 is a plan view showing the internal structure of a semiconductor device according to Embodiment 4 of the present invention, and FIGS. 29(a) and 29(b) are sectional views showing the internal structure of the semiconductor device according to Embodiment 4, in which FIG. 29(a) is a sectional view cut on line a-a of FIG. 3 and FIG. 29(b) is a sectional view cut on line b-b of FIG. 3.

As shown in FIG. 28 and FIGS. 29(a) and 29(b), the semiconductor device 32 of this Embodiment 4 is basically identical to the semiconductor device of the above-described Embodiment 1, except for the following point.

That is, the semiconductor device 32 of this Embodiment 4 has a package structure in which a semiconductor chip 33 is mounted on the main surface 2x of the semiconductor chip 2 and these two semiconductor chips are sealed with the resin sealing member 9. The semiconductor chip 33 has an integrated circuit and a plurality of bonding pads 3 formed on the main surface, and its rear surface opposite to its main surface is bonded and fixed to the main surface 2x of the semiconductor chip 2 by an adhesive 34. The bonding pads 3 of the semiconductor chip 33 are electrically connected to the respective leads 5 by respective bonding wires 35. The bonding wires 35 are connected to the respective bonding pads 3 of the semiconductor chip 33 at one end and to the respective leads 5a or leads 5b on the inner side of the terminal portions 6a of the leads 5a at the other end. For the manufacture of the semiconductor device 32 of this Embodiment 4, the batch type transfer molding method as employed in the above-described Embodiment 1 is employed.

Even in this package structure, the length of the bonding wires 35 for electrically connecting the bonding pads 3 of the semiconductor chip 33 to the respective leads 5a can be shortened. Consequently, the same effect as that of the above-described Embodiment 1 can be obtained.

### EMBODIMENTN 5

In this Embodiment 5, the present invention is applied to an SON type semiconductor device.

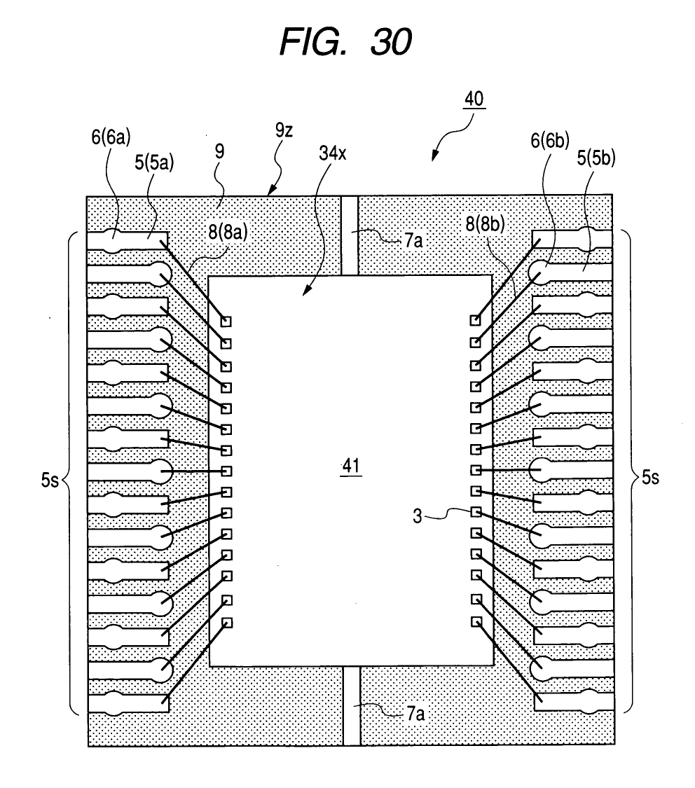

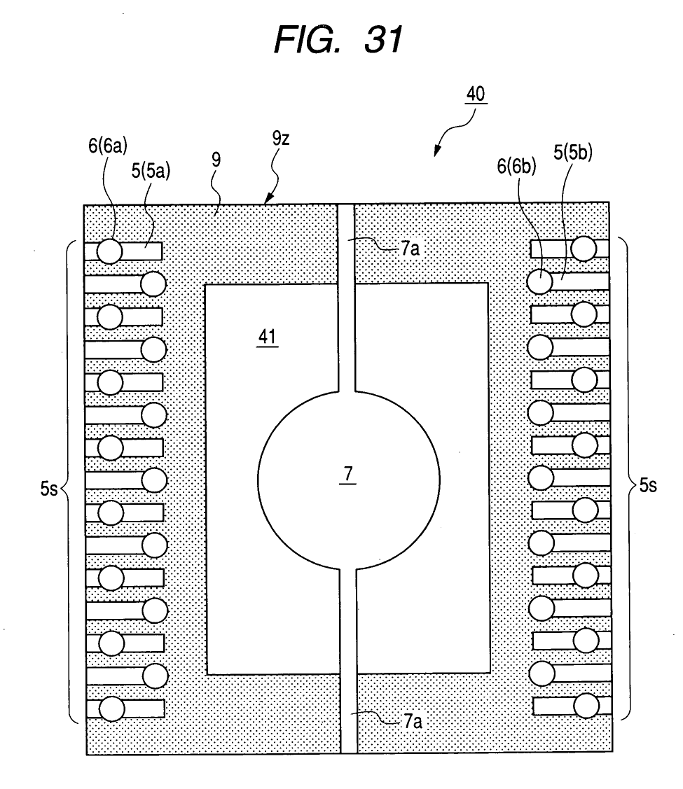

FIG. 30 is a plan view showing the internal structure of a semiconductor device according to this Embodiment 5, and FIG. 31 is a bottom view showing the internal structure of the semiconductor device according to this Embodiment 5.

As shown in FIG. 30 and 31, the semiconductor device 40 of this Embodiment 5 has a package structure having a semiconductor chip 41, first and second groups 5s of leads 5, chip substrate 7, two suspension leads 7a, a plurality of bonding wires 8, resin sealing member 9, etc. The semiconductor chip 41, the first and second groups 5s of leads 5, the chip substrate (die pad, tub) 7, the two suspension leads 7a and the plurality of bonding wires 8 are sealed with the resin sealing member 9.

The plurality of bonding pads 3 are arranged along the long opposite sides of the main surface of the semiconductor chip 41. The leads of the first group 5s are arranged external to one of the long sides of the semiconductor chip 41 and the leads of the second group 5s are arranged external to the other long side of the semiconductor chip 41. The bonding pads 3 of the semiconductor chip 41 are electrically connected to the respective leads 5 by the respective bonding wires 8. The bonding wires 8 are connected to the respective bonding pads 3 of the semiconductor chip 41 at one end and to the respective leads 5 on the inner side (semiconductor chip 2 side) of the terminal portions 6a of the leads 5a at the other end. In the manufacture of the semiconductor device 40 of this Embodiment 5, the same batch type transfer molding method as in the above-described Embodiment 1 is employed.

In this package structure, the same effect as that of the above-described Embodiment 1 is obtained.

While the invention made by the inventors of the present invention has been described with reference to the preferred embodiments thereof, it is to be understood that the invention is not limited thereto and that various changes and modifications may be made without departing from the spirit and scope thereof.

Effects obtained by typical aspects out of the invention disclosed in this application are briefly described hereinbelow.

According to the present invention, the production yield of the semiconductor device can be improved.

According to the present invention, a semiconductor device which has a high production yield and is suitable for increasing the number of pins can be provided.

1. A semiconductor device comprising:
a semiconductor chip having a plurality of electrodes arranged along one side thereof on its main surface;
a plurality of leads arranged outside the side of the semiconductor chip in the same direction as the side;
a plurality of bonding wires for electrically connecting the plurality of electrodes of the semiconductor chip to the plurality of leads, respectively; and
a resin sealing member for sealing the semiconductor chip, the plurality of leads and the plurality of bonding wires,
wherein the plurality of leads include first leads each having a terminal portion which is located at a side face of the resin sealing member and which is exposed from the rear surface of the resin sealing member, and second leads each having a terminal portion which is located at an inner side of the terminal portions of the first leads and which is exposed from the rear surface of the resin sealing member, the first leads and the second leads being arranged alternately, and
wherein the plurality of bonding wires are connected to the respective leads at the inner side of the terminal portions of the first leads.

2. The semiconductor device according to claim 1, wherein the plurality of leads extend straight toward the semiconductor chip from the side face of the resin sealing member.

3. The semiconductor device according to claim 1, wherein the first leads have a portion extending from their terminal portions toward the semiconductor chip.

4. The semiconductor device according to claim 1,
wherein one of the ends of the first leads are situated at the semiconductor chip side of their terminal portions, and
wherein one of the ends of the second leads are situated at their terminal portions.

5. The semiconductor device according to claim 1,
wherein the plurality of bonding wires include first bonding wires for electrically connecting the electrodes of the semiconductor chip to the respective first leads, and second bonding wires for electrically connecting the electrodes of the semiconductor chip to the respective second leads,
wherein the first bonding wires are connected to the first leads at the semiconductor chip side of the terminal portions of the first leads, and
wherein the second bonding wires are connected to the terminal portions of the second leads.

6. The semiconductor device according to claim 5, wherein wire connection portions in which the first bonding wires are connected to the first leads and wire connection portions in which the second bonding wires are connected to the second leads are arranged almost linearly in the same direction as the arrangement direction of the plurality of leads.

7. The semiconductor device according to claim 1,
wherein the plurality of bonding wires include first bonding wires for electrically connecting the electrodes of the semiconductor chip to the first leads, and second bonding wires for electrically connecting the electrodes of the semiconductor chip to the second leads, and
wherein the first and second bonding wires are connected to the first and second leads at the inner side of the terminal portions of the second leads, respectively.

8. The semiconductor device according to claim 1, wherein portions other than the terminal portions of the first and second leads are thinner than the terminal portions.

9. The semiconductor device according to claim 8, wherein a level difference is provided between the terminal portions and other portions of the first and second leads and is formed by etching.

10. The semiconductor device according to claim 8, wherein a level difference is provided between the terminal portions and other portions of the first and second leads and is formed by coining.

11. The semiconductor device according to claim 1, wherein the terminal portions of the first and second leads are formed by bending.

12. The semiconductor device of claim 1, wherein the width of the terminal portions of the first and second leads is larger than the width of the end portions at the side face of the resin sealing member of the first and second leads.

13. The semiconductor device according to claim 1, wherein the pitch of the end portions, at the semiconductor chip sides of the plurality of leads is almost the same as the pitch of the end portions, at the side face of the resin sealing member, of the leads.

14. The semiconductor device according to claim 1,
wherein the device further comprises a chip mounting portion where the semiconductor chip is mounted, and
wherein the outer size of the chip mounting portion is smaller than the outer size of the semiconductor chip.

15. The semiconductor device according to claim 1, wherein a plating layer essentially comprised of Pd is formed over wire connection surfaces of the first and second leads.

16. (canceled)

17. (canceled)
